(19) United States
(12) Patent Application Publication
(10) Pub. No.: US 2025/0151243 A1
(43) Pub. Date: May 8, 2025

(54) ELECTRICAL SYSTEM AND ELECTRICAL DRIVE UNIT

(71) Applicant: Schaeffler Technologies AG & Co. KG, Herzogenaurach (DE)

(72) Inventors: Johannes Herrmann, Achern (DE); Sebastian Jackstädt, Hilden (DE); Nicolai Gramann, Renchen (DE)

(73) Assignee: Schaeffler Technologies AG & Co. KG, Herzogenaurach (DE)

(21) Appl. No.: 18/832,512

(22) PCT Filed: Jan. 27, 2023
(86) PCT No.: PCT/DE2023/100063

§ 371 Date: Jul. 24, 2024

(30) Foreign Application Priority Data
Feb. 2, 2022 (DE) 10 2022 102 409.1

(51) Int. Cl. H05K 7/20

(52) U.S. Cl. CPC H05K 7/209; H05K 7/20509

(57) ABSTRACT

An electrical system with optimised heat dissipation and an electrical drive unit having the electrical system is disclosed. The electrical system has a bus bar, a housing element, and a heat-conducting element which contacts the bus bar in a thermally conductive manner. At least part of the housing element includes, on a side facing the bus bar, a shaped element which projects from an outer extension plane and forms a contact surface against which the heat-conducting element (40) bears in a thermally conductive manner.

### CROSS-REFERENCE TO RELATED APPLICATIONS

This application is the U.S. National Phase of PCT Appln. No. PCT/DE2023/100063 filed Jan. 27, 2023, which claims priority to DE 10 2022 102 409.1 filed Feb. 2, 2022, the entire disclosures of which are incorporated by reference herein.

### TECHNICAL FIELD

The disclosure relates to an electrical system with optimized heat dissipation and an electrical drive unit which comprises the electrical system.

### BACKGROUND

In electrical systems, especially those that operate with high voltage, bus bars are often used as current conductors.

Owing to the high currents involved, resistance-related heating, including of the bus bars, often occurs. In order to reduce resistance-related losses and/or to protect the bus bar itself or other adjacent components, it is often necessary or appropriate for safety reasons to dissipate heat from the bus bar. However, particularly in designs in which the bus bar is coupled to an electrically conductive module which itself has a plastic housing or a plastic covering on its outer side, heat transfer to such a module is only possible to a limited extent or is also associated with the risk of damage to the plastic of the module.

For example, so-called gap pads exist for dissipating heat. These are substantially two-dimensional bodies made of thermally conductive material in order to create thermal interfaces in air gaps between electronic components and heat sinks.

### SUMMARY

Proceeding from this, the present disclosure is based on the object of providing an electrical system and an electrical drive unit equipped therewith which ensure optimized heat dissipation.

This object is achieved by the electrical system according to the claims and the description provided in the disclosure. Advantageous embodiments of the electrical system are described herein.

The features of the claims can be combined in any technically meaningful way, it also being possible to make reference for this purpose to the explanations from the following description and features from the figures which include supplementary embodiments of the disclosure.

The disclosure relates to an electrical system with optimized heat dissipation, comprising a bus bar, a housing element and a heat-conducting element which contacts the bus bar in a thermally conductive manner. At least part of the housing element comprises, on a side facing the bus bar, a shaped element which projects from an outer extension plane and forms a contact surface against which the heat-conducting element bears in a thermally conductive manner.

The outer extension plane of the housing element is a plane in which the outer side of a boundary wall facing the bus bar extends, outside the projecting shaped element.

In one embodiment, the bus bar connects a power module and a capacitor in an electrically conductive manner. The power module and the capacitor can be components of a power electronics system that forms a high-voltage DC link between a battery or an electrical energy store and an electrical drive machine, in particular an electrically drivable motor vehicle. The capacitor can be an element of a converter that is designed to quickly supply DC voltage or direct current provided by the battery to the power module via the bus bar, said power module converting it into AC voltage.

Heat from the bus bar is transferred accordingly from the bus bar via the heat-conducting element into the housing element. Such a heat-conducting element is also called a gap pad or thermal interface material (TIM). Owing to the fact that the housing element is a large-volume component with a large mass, its specific heat capacity is high and its surfaces in relation to the surrounding air are large, so the housing element can absorb a lot of heat and/or release it to the surroundings via the surfaces by convection. This effect is further enhanced if the housing element is connected in a thermally conductive manner to other assemblies.

In accordance with the disclosure, it is therefore possible to ensure that the heat of the bus bar does not have to remain in the bus bar or does not have to be dissipated via a plastic housing that has little thermal conductivity.

This results in structurally optimized heat dissipation of the bus bar.

In an advantageous embodiment of the electrical system, the heat-conducting element is shaped three-dimensionally. The three-dimensionality serves in particular to enlarge the surface for the purpose of dissipating heat to the environment by means of convection, as well as to improve heat transfer to the housing element.

The housing element can consist of or comprise a material which has a thermal conductivity of at least 40 W/mK. In particular, the housing element can be made of a metallic material, such as cast steel or cast iron.

The heat-conducting element can consist of a material or partially comprise a material which has a thermal conductivity of at least 3 W/mK.

In particular, a silicone with ceramic and/or glass fiber additives can be used as the material for the heat-conducting element.

At the same time, the material of the heat-conducting element should have an electrically insulating effect due to a dielectric strength of at least 12 kV/mm.

Furthermore, the distance between the bus bar and the contact surface of the projecting shaped element must be a maximum of 3 mm. The heat-conducting element located in between is designed to be correspondingly thick, wherein the heat-conducting element can be arranged with a slight press fit between the bus bar and the contact surface. In an advantageous embodiment, the distance is not more than 2 mm, optionally not more than 1 mm. This means that a projecting shaped element, which forms a plateau as a contact surface, extends to the bus bar up to a minimum distance from it.

The ratio of a distance aE between the outer extension plane of the housing element and the bus bar to the distance aS between the bus bar and the contact surface of the projecting shaped element is, in an advantageous embodiment, aE/aS>4.

This means that a projecting shaped element projects relatively far from the outer extension plane in the direction of the bus bar. In this embodiment, it is possible for a projecting shaped element to be formed by the housing element only at those locations of the housing element where a heat-conducting element is to be arranged.

In a further advantageous embodiment of the electrical system, the heat-conducting element bears with at least one protrusion element against an outer side surface of the projecting shaped element. A side surface of the projecting shaped element is a surface which, in the housing element, realizes the connection between the plane in which the outer side of a boundary wall facing the bus bar extends and the contact surface of the housing element against which the heat-conducting element bears.

The projecting shaped element must be designed with a cavity that is open on the side facing the bus bar. The open cavity in the projecting shaped element has technological advantages, particularly when the housing element is manufactured using casting technology, especially when demolding the housing element.

In this embodiment, it is possible for the heat-conducting element to bear with at least one protrusion element against an inner side surface of the projecting shaped element that delimits the cavity. Although a projecting shaped element when formed with a cavity has a reduced contact surface compared to a projecting shaped element made of solid material and consequently causes increased thermal resistance when heat is conducted into the projecting shaped element, the enlarged contact surface by means of one or more protrusion elements of the heat-conducting element in turn causes a reduction in the thermal resistance, and so ultimately a projecting shaped element can be optimized in terms of casting technology and, nevertheless, sufficient heat conduction into the projecting shaped element or into the housing element is ensured.

In an advantageous embodiment of the electrical system, the electrical system has a converter and the housing element is the housing or part of a housing of the converter.

A further aspect of the present disclosure is an electrical drive unit which comprises at least one electrical rotary machine and power electronics system for controlling and/or supplying current to the electrical rotary machine, and has an electrical system according to the disclosure as a component of the power electronics system.

### BRIEF DESCRIPTION OF THE DRAWINGS

The disclosure described above is explained in detail below against the relevant technical background with reference to the associated drawings, which show preferred embodiments. The disclosure is in no way limited by the purely schematic drawings and it should be noted that the exemplary embodiments shown in the drawings are not limited to the dimensions shown. In the drawings:

FIG. 1: shows the electrical system in a sectional view;

FIG. 2: shows a plan view of the housing element with projecting shaped elements.

### DETAILED DESCRIPTION

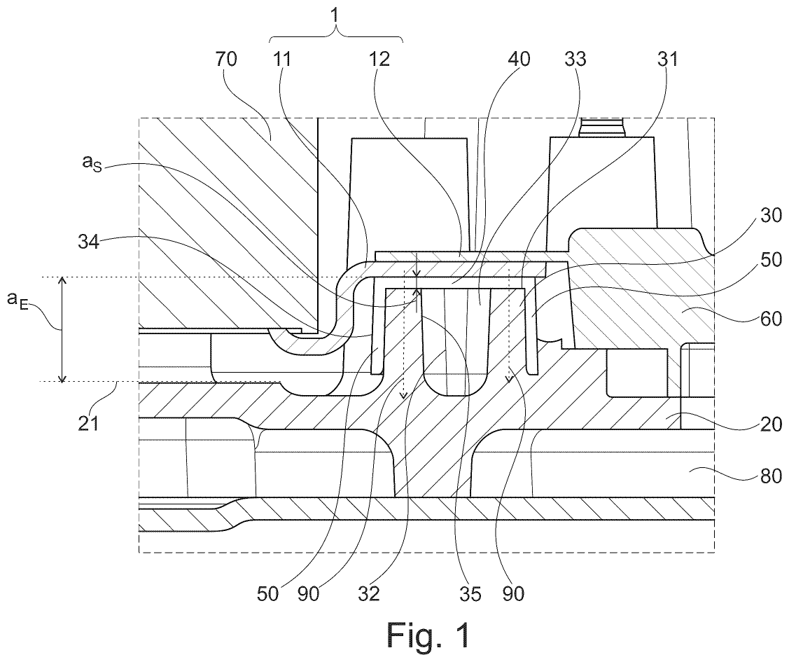

The electrical system according to the disclosure shown in FIG. 1 comprises a bus bar 1 which is composed of a first part 11 of the bus bar 1 and a second part 12 of the bus bar 1. In particular, these two parts 11, 12 of the bus bar 1 are welded together.

The bus bar 1 connects a capacitor 70, which can have a plastic covering, for example, to a power module 60.

Below the bus bar 1, there is a housing element 20 which forms a housing or part of a housing of a converter 80 of the electrical system.

The housing element 20 comprises a shaped element 30 which projects from an outer extension plane 21, which generally forms an outer side of the housing element 20. The projecting shaped element 30 forms a contact surface 31 with which the projecting shaped element 30 bears against a heat-conducting element 40 in a thermally conductive manner. The heat-conducting element 40 in turn bears against the first part 11 of the bus bar 1 in a thermally conductive manner.

Accordingly, heat can be transferred from the bus bar 1 via the heat-conducting element 40 into the projecting shaped element 30 or into the housing element 20, substantially along the outlined heat flow 90.

In order to improve the heat conduction from the bus bar 1 into the housing element 20, the heat-conducting element 40 in the embodiment shown here comprises two protrusion elements 50 which extend from the plane of the contact surface 31 in the direction of the outer extension plane 21 of the housing element 20.

In the embodiment shown here, the protrusion elements 50 each extend along the outer side surface 34 of the projecting shaped element 30 in order to also transfer heat there into the projecting shaped element 30.

The projecting shaped element 30 is designed with a cavity 32 which forms an opening 33 in the contact surface 31.

Accordingly, alternatively or additionally, at least one protrusion element could also be present which extends along the inner side surface 35 of the projecting shaped element 30 and bears against same in order to introduce heat into the projecting shaped element 30.

It can be seen that the distance aS between the bus bar 1 and the contact surface 31 is much smaller than the distance aE between the bus bar 1 and the outer extension plane 21 of the housing element 20. This means that the projecting shaped element 30 makes a significantly greater contribution to bridging the distance between the outer extension plane 21 of the housing element 20 than the heat-conducting element 40.

The elements described here are components of a power electronics system, in particular a power electronics system for an electrically drivable motor vehicle.

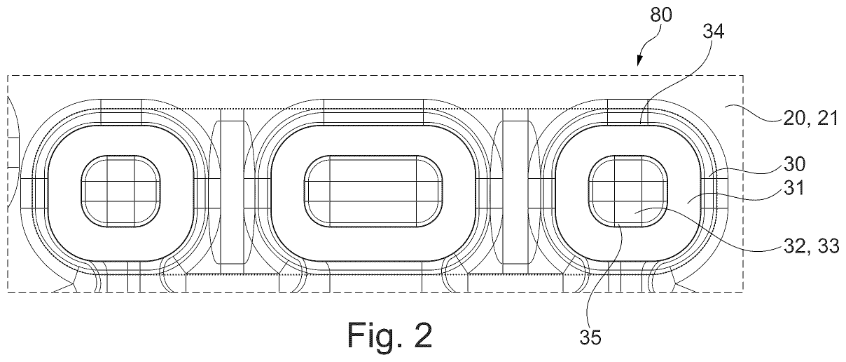

FIG. 2 shows the housing element 20 of the converter 80 in plan view. It is clearly visible here that a contact surface 31 has an opening 33 which leads to the cavity 32 arranged in the interior of the projecting shaped element 30.

Although this increases the thermal resistance when heat is introduced into a projecting shaped element 30, sufficient heat conduction into the protruding shaped element 30 or the housing element 20 is ensured due to the described arrangement of protrusion elements 50, which are shown in FIG. 1.

The electrical system proposed here and the electrical drive unit equipped therewith provide devices that ensure optimized heat dissipation.

### List of Reference Signs

1 Bus bar
11 First part of the bus bar
12 Second part of the bus bar
20 Housing element
21 Outer extension plane
30 Projecting shaped element
31 Contact surface
32 Cavity
33 Opening
34 Outer side surface of the projecting shaped element
35 Inner side surface of the projecting shaped element
40 Heat-conducting element
50 Protrusion element
60 Power module
70 Capacitor
80 Converter
90 Heat flow
aS Distance between the bus bar and the contact surface
aE Distance between the bus bar and the outer extension plane

1. An electrical system, comprising
a bus bar,
a housing element, and
a heat-conducting element which contacts the bus bar in a thermally conductive manner, wherein at least part of the housing element comprising, on a side facing the bus bar, a shaped element which projects from an outer extension plane and forms a contact surface against which the heat-conducting element bears in a thermally conductive manner.

2. The electrical system according to claim 1, wherein the heat-conducting element is shaped three-dimensionally.

3. The electrical system according to claim 1, wherein the housing element comprises a material which has a thermal conductivity of at least 40 W/mk.

4. The electrical system according to claim 1, wherein the heat-conducting element comprises a material which has a thermal conductivity of at least 3 W/mK.

5. The electrical system according to claim 1, wherein a distance between the bus bar and the contact surface of the projecting shaped element is a maximum of 3 mm.

6. The electrical system according to claim 1, wherein the heat-conducting element bears with at least one protrusion element against an outer side surface of the projecting shaped element.

7. The electrical system according to claim 1, wherein the projecting shaped element is designed with a cavity which is open on the side facing the bus bar.

8. The electrical system according to claim 7, wherein the heat-conducting element bears with at least one protrusion element against an inner side surface of the projecting shaped element, which delimits the cavity

9. The electrical system according to claim 1, further comprising a converter, and wherein the housing element is a part of a housing of the converter.

10. An electrical drive unit, comprising at least one electrical rotary machine and a power electronics system for controlling and/or supplying current to the electrical rotary machine, and an electrical system according to claim 1 as a component of the power electronics system.
